(19) United States
(12) Patent Application Publication
(10) Pub. No.: US 2015/0262915 A1
(43) Pub. Date: Sep. 17, 2015

(54) SEMICONDUCTOR DEVICE AND MODULE

(71) Applicant: KABUSHIKI KAISHA TOSHIBA, Tokyo (JP)

(72) Inventor: Miwako SUZUKI, Kawasaki Kanagawa (JP)

(21) Appl. No.: 14/471,855

(22) Filed: Aug. 28, 2014

(30) Foreign Application Priority Data
Mar. 13, 2014 (JP) 2014-050691

(51) Int. Cl. H01L 23/492; H01L 23/00; H01L 29/78

(52) U.S. Cl. CPC H01L 23/4924; H01L 29/7827; H01L 24/30; H01L 2224/30181; H01L 2224/29023; H01L 2224/29006; H01L 2224/32225

(57) ABSTRACT

According to an embodiment, a semiconductor device includes a first conductive plate having a semiconductor chip mounted thereon, and a second conductive plate that overlaps the semiconductor chip and at least two sides of the first conductive plate. In some embodiments, the semiconductor chip includes a source electrode, a drain electrode, and a gate electrode, and the first conductive plate includes a first terminal electrically connected to the drain electrode and a second terminal electrically connected to the gate electrode; a third terminal on the second conductive plate is provided on the at least two sides and electrically connected to the source electrode.

### CROSS-REFERENCE TO RELATED APPLICATION

This application is based upon and claims the benefit of priority from Japanese Patent Application No. 2014-050691, filed Mar. 13, 2014, the entire contents of which are incorporated herein by reference.

### FIELD

Embodiments described herein relate generally to a semiconductor device and a module.

### BACKGROUND

It is difficult to ignore the electric resistance of semiconductor device connections as chips with a low overall electric resistance are developed. For example, when the semiconductor device is electrically connected to a source electrode using a metal plate (for example, a source connector) which covers up the entire chip surface, a lower resistance value is achieved as compared to when the semiconductor device is electrically connected to the source electrode using a wire bonding. However, still further reduction of the electric resistance of the semiconductor device is required.

### DESCRIPTION OF THE DRAWINGS

FIG. 1 is a top view illustrating a schematic configuration of a semiconductor device according to a first embodiment.

FIG. 2 is a cross-sectional view illustrating an example of a module which includes the semiconductor device illustrated in FIG. 1.

FIG. 3 is a perspective view illustrating an example of the module which includes the semiconductor device illustrated in FIG. 1.

FIG. 4 is a top view illustrating a semiconductor device according to a reference example.

FIG. 5 is a top view illustrating one modification example of the semiconductor device according to the first embodiment.

FIG. 6 is a top view illustrating a schematic configuration of a semiconductor device according to a second embodiment.

FIG. 7 is a top view illustrating a schematic configuration of a semiconductor device according to a third embodiment.

FIG. 8 is a top view illustrating a schematic configuration of a semiconductor device according to a fourth embodiment.

FIG. 9 is a top view illustrating a schematic configuration of a semiconductor device according to a fifth embodiment.

### DETAILED DESCRIPTION

An embodiment provides a semiconductor device and a module having a reduced a source connector electrical resistance.

According to an embodiment, a semiconductor device includes a first conductive plate having a semiconductor chip mounted thereon, and a second conductive plate that overlaps the semiconductor chip and at least two sides of the first conductive plate. In some embodiments, the semiconductor chip includes a source electrode, a drain electrode, and a gate electrode, and the first conductive plate includes a first terminal electrically connected to the drain electrode and a second terminal electrically connected to the gate electrode; a third terminal on the second conductive plate is provided on the at least two sides and electrically connected to the source electrode.

In general, according to one embodiment, there is provided a semiconductor device including: a semiconductor chip, a first conductive plate and a second conductive plate. The first conductive plate is mounted with the semiconductor chip, and a circumference thereof is configured by at least four sides/edges. The second conductive plate covers the semiconductor chip and at least two sides/edges of the first conductive plate.

Hereinafter, some of the embodiments will be described referring to accompanying drawings. In the drawings, same reference numerals refer to same elements, and a duplicated description thereof is appropriately omitted.

The accompanying drawings are intended to promote description and understanding of the embodiments, respectively, and it should be noted that shapes, sizes, and dimensional ratios in each drawing may be different from those of an actual device. These differences may be appropriately modified in design by those skilled in the art considering a following description and known technologies.

### (1) First Embodiment

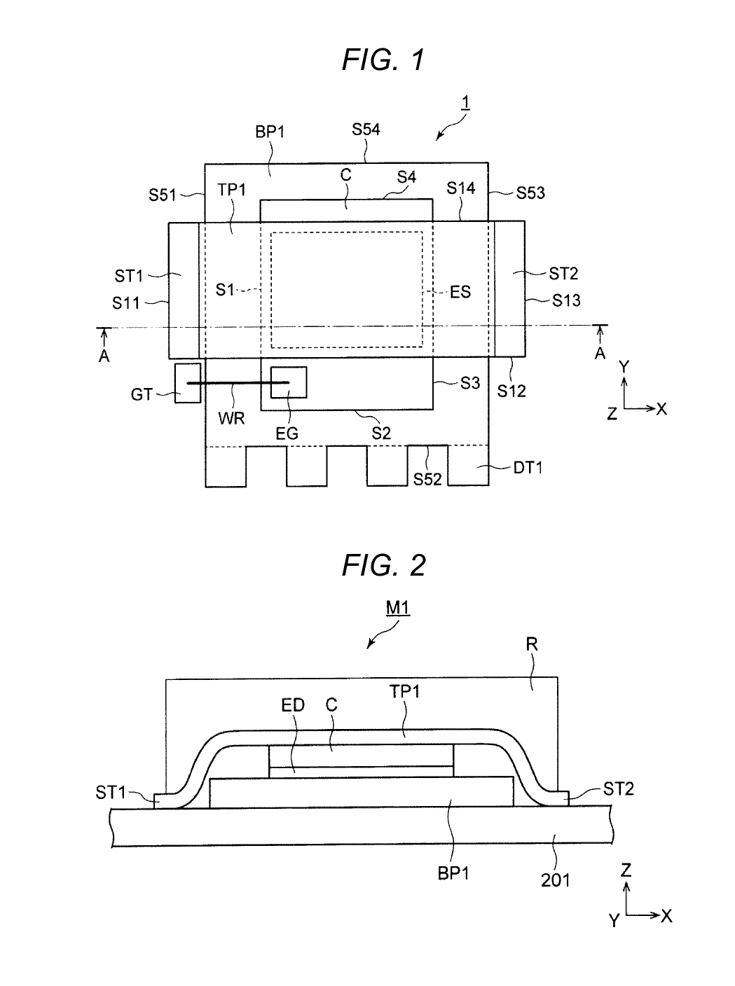

FIG. 1 is a top view illustrating a schematic configuration of a semiconductor device according to the first embodiment.

A semiconductor device 1 according to the present embodiment includes a drain frame BP1, a semiconductor chip C, a source connector TP1, and a gate terminal GT. The semiconductor chip C according to the embodiment includes a power Metal Insulator Semiconductor Field Effect Transistor (MISFET), having a source electrode ES, a drain electrode ED (refer to FIG. 2), and a gate electrode EG.

The semiconductor chip C is mounted on the drain frame BP1, and is connected to the drain frame BP1 using solder or the like.

The drain electrode ED is provided on a back surface side of the semiconductor chip C in this embodiment and is electrically connected to the drain frame BP1.

The gate electrode EG is connected to a gate terminal GT through a wire WR.

A source electrode ES is provided on the upper surface side of the semiconductor chip C, and a source connector TP1 is provided so as to cover the semiconductor chip C while being in contact with the source electrode ES, and thereby the source electrode ES is electrically connected to the source connector TP1. In the first embodiment, the source electrode ES, the drain electrode ED and the gate electrode EG correspond to, for example, a first electrode to a third electrode, respectively.

Both the drain frame BP1 and the source connector TP1 are formed from a conductor, and are formed from, for example, copper (Cu) in the first embodiment. This also applies to the drain frames BP3, BP4, and BP11, and the source connectors TP2 to TP5 to be described below. The drain frame BP1 and the source connector TP1 correspond, respectively, to, for example, the first conductive plate and the second conductive plate in the present embodiment.

The semiconductor chip C has a rectangular planar shape in the first embodiment, and a circumference (perimeter) of the semiconductor chip C is configured to have four edges (sides) S1 to S4.

The source connector TP1 extends horizontally (e.g., parallel to a plane of the semiconductor chip C) after a bent transition (that is, source connector TP1 is bent downwardly at its right and left ends in FIG. 1 (refer also to FIG. 2)). The bent transitions are spaced from the perimeter of the semiconductor chip C—that is, source connector TP1, in this first embodiment, (as depicted in FIG. 2) extends horizontally beyond the perimeter of the semiconductor chip C before the bent transition begins. Source terminals ST1 and ST2 are provided in each of the extended portions after the bent transition region. A bottom surface of the source terminals ST1 and ST2 is configured so as to be at the same level as a back surface of the drain frame BP1.

One feature of the semiconductor device 1 in the first embodiment is that the source connector TP1 has a rectangular shape whose circumference is configured to have four edges S11 to S14 which each are parallel to four edges S1 to S4 that configure a circumference of the semiconductor chip C, and source terminals ST1 and ST2 are provided at edges S11 and S13, which extend in a Y direction and oppose each other in a X direction.

The drain terminal DT1 is provided at one edge S52 of the drain frame BP1 along an edge S12 which is adjacent to the edges S11 and S13 and extends in the X direction.

As described above, according to the semiconductor device 1 according to the first embodiment, the source connector TP1 is disposed so as to cover the semiconductor chip and two edges S51 and S53 of the drain frame BP1, and furthermore, a plurality of source terminals ST1 and ST2 are provided along at least two edges S11 and S13 among the four edges S11 to S14, so that a source current flows in from both a ST1 side and a ST2 side of the source connector TP1. Accordingly, an electric resistance of the source connector may be reduced.

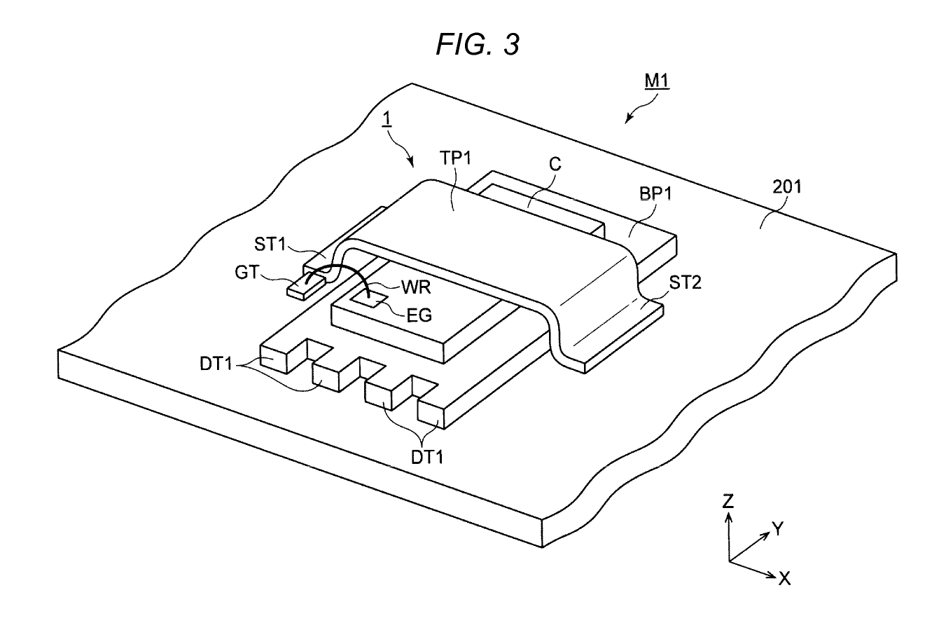

FIGS . 2 and 3 illustrate an example of a module in which the semiconductor device 1 illustrated in FIG. 1 is mounted on a wiring board 201. FIG. 2 corresponds to a cross-section taken along a section line of A-A in FIG. 1, and is furthermore a cross-sectional view illustrating a module M1. FIG. 3 is a perspective view illustrating the module M1. In the module M1 illustrated in FIGS . 2 and 3, a source electrode ES of the semiconductor chip C is electrically connected to the wiring board 201 through the source connector TP1. The gate electrode EG of the semiconductor chip C is electrically connected to the wiring board 201 through the wire WR and the gate terminal GT. The drain electrode ED of the semiconductor chip C is electrically connected to the wiring board 201 through the drain frame BP1.

In addition, the module M1 also includes a resin R which seals (encapsulates) the semiconductor device 1 as illustrated in FIG. 2.

According to the module M1 according to the first embodiment, there is provided a module in which the semiconductor device 1 has a reduced electric resistance of the source connector with the mounting to the wiring board 201. This similarly applies when mounting the semiconductor devices according to the second to fifth embodiments, to be described below, on the wiring board 201 or the equivalent.

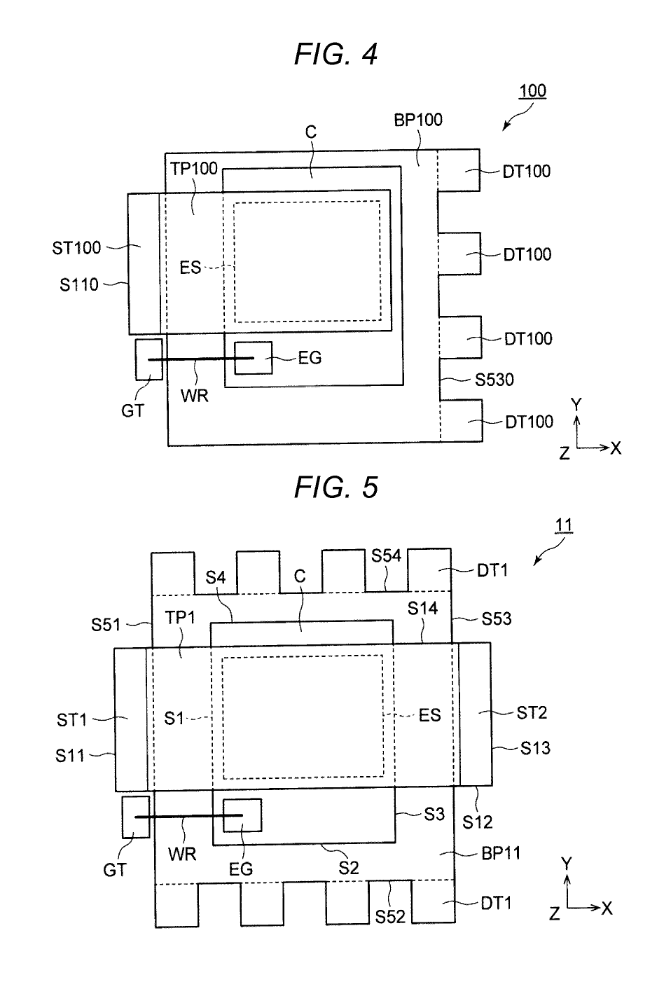

FIG. 4 is a reference example. The semiconductor device 100 in FIG. 4 includes a drain frame BP100, the semiconductor chip C on the drain frame BP100, and a source connector TP100 on the semiconductor chip C.

In the semiconductor device 100 of the reference example, among the four edges S110 to S140 configuring a circumference of the source connector TP100, a source terminal ST100 is provided only on a side of an edge S110.

In general, an electric resistance of a packaged device is mostly the result of an electric resistance of the drain frame and an electric resistance of the source connector. In the semiconductor device 100 of the reference example, a drain current flows in the semiconductor chip C from the drain frame BP100 and is drawn to the source terminal ST100 through the source connector TP100. The drain frame BP100 at this time has a low electric resistance since a distance from the drain terminal DT100 to the semiconductor chip C is short.

However, a path of the source current is from the source electrode ES of the semiconductor chip C to the source terminal ST100 of the source connector TP100. The distance therebetween is longer than a path of the drain current. Therefore, an electric resistance of the source connector TP100 becomes higher than an electric resistance of the drain frame BP100.

Therefore, as in the first embodiment described above, the source terminal may be provided on at least two edges among the four edges which form a circumference of the source connector TP1, and this thereby allows the source current to flow in both the ST1 side and the ST2 side, which lowers the electric resistance of the source connector. Accordingly, the drain terminal is disposed at a position along a remaining edge at which the source terminal is not provided. In a specific example of the first embodiment, the drain terminal DT1 is provided on the edge S52 along the edge S12 of the source connector TP1.

However, the drain terminal DT1 does not need to be disposed only along the edge S52, and may be instead (or also) disposed on an edge S54 side opposed to the edge S52.

FIG. 5 is one modification example of the semiconductor device 1 according to the first embodiment illustrated in FIG. 1.

By comparison with FIG. 1, the semiconductor device 11 of the modification example further includes a drain terminal DT2 provided along the edge S54 confronting (opposing) the edge S52 in addition to a drain terminal DT1 provided along the edge S52 of the drain frame BP11.

With this configuration, according to the semiconductor device 11 according to the modification example, reduction in both of an electric resistance of the source connector TP1 and an electric resistance of the drain frame BP11 is achieved.

### (2) Second Embodiment

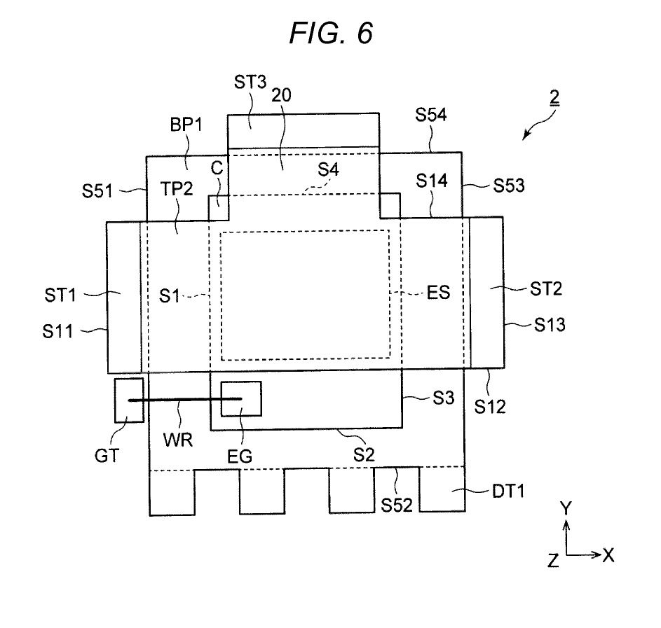

FIG. 6 is a top view illustrating a schematic configuration of a semiconductor device according to the second embodiment.

By comparison with FIG. 1, a semiconductor device according to the second embodiment includes a source connector TP2 instead of the source connector TP1 depicted in FIG. 1. The source connector TP2 includes a protruding portion 20 which extends outwardly from the edge S14 adjacent to the edges S11 and S13 confronting each other and covers the edge S54 of the drain frame BP1, and a source terminal ST3 is further provided in the protruding portion 20. The other configurations of the semiconductor device 2 are substantially the same as of the semiconductor device 1 illustrated in FIG. 1.

As described above, the semiconductor device 2 according to the second embodiment includes the source terminals ST1 to ST3 which are provided on three adjacent edges S11, S14, and S13, respectively, so that the source current flows in three paths. Accordingly, it is possible to further reduce an electric resistance of the source connector TP2.

### (3) Third Embodiment

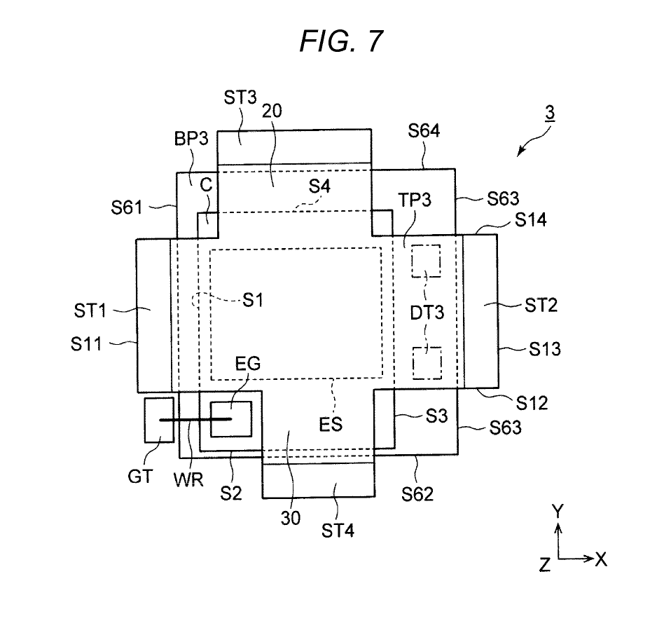

FIG. 7 is a top view illustrating a schematic configuration of a semiconductor device according to the third embodiment.

By comparison with FIG. 6, a semiconductor device 3 according to the third embodiment includes a source connector TP3 instead of the source connector TP2 in FIG. 6, and includes a drain frame BP3 instead of the drain frame BP1.

The source connector TP3 includes a protruding portion 30 which extends outwardly from the edge S12 (confronting the edge S14) to cover an edge S62 of the drain frame BP3, and extends outwardly in a horizontal manner after being bent to a drain frame BP3 side, and a source terminal ST4 is further provided at the protruding portion 30.

The drain frame BP3 has a rectangular shape in which four edges S61 to S64 configure a circumference, and the drain terminals DT3 are provided on the back surface side of the drain frame.

In this manner, the semiconductor device 3 according to the third embodiment includes the source terminals ST1 to ST4 each provided along all of the four adjacent edges S11 to S14, so that the source current flows in four paths. Accordingly, it is possible to further reduce an electric resistance of the source connector TP3.

Moreover, the semiconductor device 3 according to the third embodiment may radiate heat at a high efficiency since the source connector TP3 substantially covers the semiconductor chip C and the drain frame BP3.

### (4) Fourth Embodiment

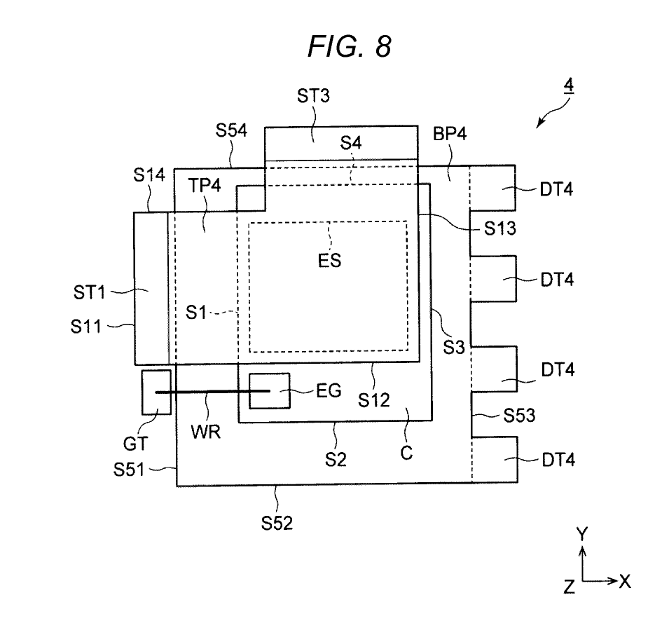

FIG. 8 is a top view illustrating a schematic configuration of a semiconductor device according to the fourth embodiment. By comparison with FIG. 1, a semiconductor device 4 according to the fourth embodiment includes a drain frame BP4 in which a drain terminal DT4 is provided on an edge S53, the semiconductor chip C, a source connector TP4, and the gate terminal GT.

The source connector TP4 has an L-shaped planar shape, and the source terminals ST1 and ST3 are provided along two edges S11 and S14 adjacent to each other, respectively.

As described above, according to the semiconductor device 4 according to the fourth embodiment, the source terminals ST1 and ST3 are provided respectively along the two adjacent edges S11 and S14 among the four edges S11 to S14 which configure a circumference of the source connector TP4, so that the source current flows in both the ST1 side and the ST3 side in the source connector TP4. Accordingly, it is possible to reduce an electric resistance of the source connector TP4.

In the fourth embodiment, the drain terminal DT4 is provided on the edge S53 of the drain frame BP4, however, the exemplary embodiment is not limited thereto, and the drain terminal DT4 may be provided on, for example, the edge S52.

### (5) Fifth Embodiment

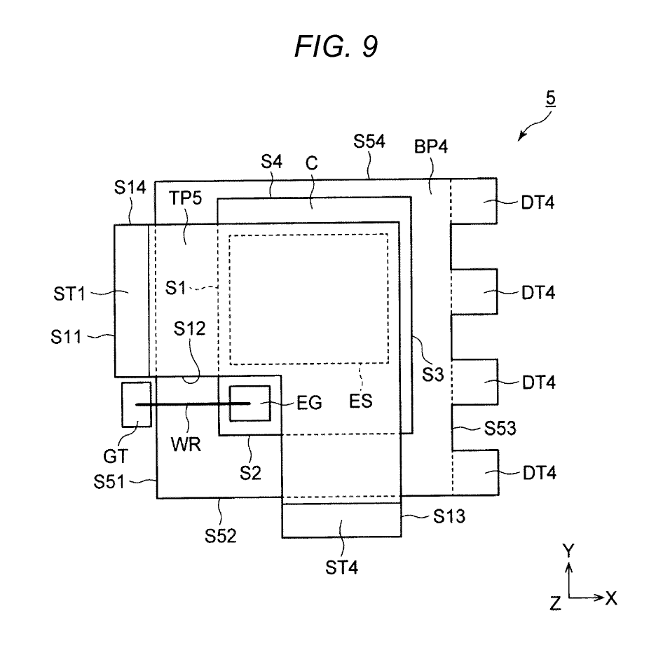

FIG. 9 is a top view illustrating a schematic configuration of a semiconductor device according to the fifth embodiment.

A semiconductor device 5 according to the fifth embodiment includes a source connector TP5 which has an L-shape similar to a shape obtained by vertically inverting the source connector TP4 in FIG. 8, and the source terminals ST1 and ST4 are provided along two adjacent edges S11 and S12, respectively. A configuration of the semiconductor device 5 is substantially the same as the configuration of the semiconductor device 4 illustrated in FIG. 8 except that a disposition direction of the source connector TP5 in an L-shape is different and the source terminals ST1 and ST4 are provided along the edges S11 and S12.

According to the semiconductor device 5 according to the fifth embodiment, it is possible to reduce an electric resistance of the source connector TP5 with this configuration.

In the fifth embodiment, the drain terminal DT4 of the drain frame BP4 may be provided on, for example, the edge S54 and/or provided on the edge S53.

According embodiments described above, a source connector includes a source terminal connected to a source electrode provided along at least two edges among a first edge to a fourth edge which configure a circumference of the source connector, and thereby it is possible to reduce the electric resistance of the source connector.

In addition, according at least one embodiment described above, a module mounted with a semiconductor device having reduced electric resistance of the source connector is provided.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device, comprising:
a first conductive plate having a semiconductor chip mounted thereon; and
a second conductive plate that overlaps the semiconductor chip and at least two sides of the first conductive plate.

2. The device according to claim 1, wherein
the semiconductor chip includes a source electrode, a drain electrode, and a gate electrode,
the first conductive plate includes a first terminal electrically connected to the drain electrode and a second terminal electrically connected to the gate electrode, and
the second conductive plate includes a third terminal provided on the at least two sides and electrically connected to the source electrode.

3. The device according to claim 2, wherein the first terminal is provided along a side other than the at least two sides at which the third terminal is provided.

4. The device according to claim 3, wherein the first terminal is provided along two sides other than the at least two sides at which the third terminal is provided.

5. The device according to claim 1, wherein
the semiconductor chip includes a first electrode, a second electrode, and a third electrode,
the first conductive plate includes a first terminal electrically connected to the first electrode and a second terminal connected to the second electrode,
the second conductive plate includes a third terminal electrically connected to the third electrode, and
the at least two sides of the first conductive plate which are overlapped by the second conductive plate are adjacent.

6. The device according to claim 5, wherein the first terminal is provided along any side of the first conductive plate other than the at least two sides

7. The device according to claim 1, wherein
the semiconductor chip includes a first electrode, second electrode, and a third electrode,
the first conductive plate includes a first terminal electrically connected to the first electrode and a second terminal connected to the second electrode and
the second conductive plate includes a third terminal electrically connected to the third electrode and provided along three sides of the second conductive plate, and
the second conductive plate overlaps three sides of the first conductive plate.

8. The device according to claim 7, wherein the first terminal is provided along a side of the first conductive plate other than those sides of the first conductive plate that are overlapped by the second conductive plate.

9. The device according to claim 1, wherein
the semiconductor chip includes a first electrode, a second electrode, and a third electrode,
the first conductive plate includes a first terminal electrically connected to the first electrode and a second terminal connected to the second electrode, and
the second conductive plate includes a third terminal electrically connected to the third electrode and provided along four sides of the second conductive plate, and
the second conductive plate overlaps four sides of the first conductive plate.

10. The device according to claim 9, wherein the first terminal is provided on a surface of the first conductive plate that is opposite a surface on which the semiconductor chip is mounted.

11. A module including a semiconductor device, comprising:
a first conductive plate having a semiconductor chip mounted thereon;
a second conductive plate that overlaps the semiconductor chip and at least two sides of the first conductive plate; and
a substrate on which the first conductive plate is provided.

12. The module according to claim 11, wherein
the semiconductor chip includes a source electrode, a drain electrode, and a gate electrode,
the first conductive plate includes a first terminal electrically connected to the drain electrode and a second terminal electrically connected to the gate electrode, and
the second conductive plate includes a third terminal provided on the at least two sides and electrically connected to the source electrode.

13. The module according to claim 12, wherein the first terminal is provided along a side other than the at least two sides along which the third terminal is provided.

14. The module according to claim 11, wherein
the semiconductor chip includes a first electrode, a second electrode, and a third electrode,
the first conductive plate includes a first terminal electrically connected to the first electrode and a second terminal connected to the second electrode,
the second conductive plate includes a third terminal electrically connected to the third electrode, and
the at least two sides of the first conductive plate which are overlapped by the second conductive plate are adjacent.

15. The module according to claim 11, wherein
the semiconductor chip includes a first electrode, a second electrode, and a third electrode,
the first conductive plate includes a first terminal electrically connected to the first electrode and a second terminal connected to the second electrode, and
the second conductive plate includes a third terminal electrically connected to the third electrode and provided along four sides of the second conductive plate, and
the second conductive plate overlaps the semiconductor chip and four sides of the first conductive plate.

16. The module according to claim 15, wherein the first terminal is provided on a surface of the first conductive plate that is opposite a surface on which the semiconductor chip is mounted.

17. A semiconductor device, comprising:
a first conductive plate to which a semiconductor chip is mounted, the semiconductor chip having a source electrode, a drain electrode, and a gate electrode, the drain electrode being electrically connected to a drain terminal on the first conductive plate; and
a second conductive plate including a source terminal, the source electrode being electrically connected to the source terminal, the second conductive plate covering the semiconductor chip and extending beyond at least two sides of the first conductive plate when viewed from a first direction orthogonal to a plane of the semiconductor chip.

18. The semiconductor device of claim 17, wherein the source terminal is along any sides of the second conductive plate which extend beyond the at least two sides of the first conductive plate.

19. The semiconductor device of claim 17, wherein the second conductive plate has a first portion at a first level above the semiconductor chip along the first direction, a second portion below the semiconductor chip along the first direction, and a third portion which connects between the first and second levels.

20. The device according to claim 17, wherein the second conductive plate extends beyond four sides of the first conductive plate.
